(19) United States
(12) Patent Application Publication
(10) Pub. No.: US 2005/0082575 A1
(43) Pub. Date: Apr. 21, 2005

(54) Structure and manufacturing method for GaN light emitting diodes

(76) Inventors: Lung-Chien Chen, Hsin-Chuang City (TW); Wen-How Lan, Taoyuan City (TW); Fen-Ren Chien, Yung-Ho City (TW)

Correspondence Address: SUPREME PATENT SERVICES, POST OFFICE BOX 2339, SARATOGA, CA, 95070, US

(21) Appl. No.: 11/005,110

(22) Filed: Dec. 4, 2004

Related U.S. Application Data
(62) Division of application No. 10/283,886, filed on Oct. 29, 2002.

(51) Int. Cl. H01L 31/0296

(52) U.S. Cl. 257/202

(57) ABSTRACT

The present invention provides a structure and a manufacturing method of GaN light emitting diodes. First, a substrate is provided. Then, a GaN semiconductor stack layer is formed on top of the substrate. The said GaN semiconductor stack layer includes, from the bottom up, an N-type GaN contact layer, a light emitting stack layer and a P-type contact layer. The next step is to form a digital transparent layer on said P-type GaN contact layer, then use dry etching technique to etch downward through the digital transparent layer, the P-type GaN contact layer, the light emitting layer, the N-type GaN contact layer, and form an N-metal forming area within the N-type GaN contact layer. The next step is to form a first ohmic contact electrode on the P-type contact layer to serve as P-type ohmic contact, and a second ohmic contact electrode on the N-metal forming area to serve as N-type ohmic contact. Finally, a bump pad is formed on the first ohmic contact electrode and the second ohmic contact electrode, respectively.

### CROSS-REFERENCES TO RELATED APPLICATIONS

This is a division of U.S. application Ser. No. 10/283,886, filed Oct. 29, 2002.

### FIELD OF THE INVENTION

This invention relates to a structure and a manufacturing method for light emitting diodes (LED), and more specially to a structure and a manufacturing method for ohmic contact of light emitting diodes made of GaN or other wide bandgap materials.

### BACKGROUND OF THE INVENTION

As shown in FIG. 1, a conventional GaN light emitting diodes has a structure comprising of (1) a substrate 1, (2) a buffer layer 2 formed on top of said substrate 1, (3) an N-type GaN layer 3 formed on top of said buffer layer 2, (4) a light emitting stack layer formed on top of said N-type GaN layer 3, and (5) a P-type GaN layer 5 formed on top of said light emitting stack layer 4. It is manufactured with the following method: (1) As shown in FIG. 2A, using the inductively coupled plasma-reactive ion etching (ICP-RIE) dry etching technique, this step etches downwards through the P-type GaN layer 5, light emitting stack layer 4, and reaches the N-type GaN layer 3 to form an N-Metal forming area 6 of depth about 10,000 Å; (2) As shown in FIG. 2B, a transparent conductive layer (TLC) 7, which could be used as a P-type ohmic contact, is formed on top of P-type GaN layer 5; (3) As shown in FIG. 2C, an N-Metal 8, which could be used as an N-type ohmic contact, is formed on N-Metal forming area 6; and (4) As shown in FIG. 2D, a bump pad 9 with the diameter about 100 um is formed on both TCL 7 and N-Metal 8. A conventional GaN LED could be manufactured by following the aforementioned steps.

In the aforementioned steps, TCL 7, N-Metal 8, and bump pad 9 are formed by electronic gun vapor-phase steam electroplate technique, or other similar techniques, such as heat-resist vapor-phase steam electroplate, or splash vapor-phase steam electroplate. The TCL 7 is made of Ni/Au of size about 50 Å/50 Å, or other materials, such as NiCr/Au, or Ni/Aube. The N-Metal 8 is made of Ti/Al of size about 150 Å/1500 Å, or other materials, such as Ti/Al/Ti/Au (150 Å/1500 Å/2000 Å/1000 Å), or Ti/Al/Ni/Au (150 Å/1500 Å/2000 Å/1000 Å). The bump pad 9 is made of Ti/Au (150 Å/20000 Å), or other materials, such as, Ti/Al/Ti/Au (150 Å/1500 Å/2000 Å/10000 Å), or Ti/Al/Pt/Au (150 Å/1500 Å/2000 Å/10000 Å).

However, the structure and its ohmic contact of the conventional GaN LED manufactured with the aforementioned method suffer a problem. Because the material used for TCL 7, Ni/Au, has a low photo-penetrability, it is necessary to be very thin (about 50 Å) to have a photo-penetrability of 70%. Nevertheless, at this thickness, the electrical conductivity decreases. Thus, it is difficult to improve the operating voltage (Vf) and the illumination (Iv) of the conventional GaN LED effectively. To solve the problem, a new structure need to be devised.

### SUMMARY OF THE INVENTION

The first goal of the present invention is to provide a structure and a manufacturing method of GaN Leds with a digital transparent layer.

The second goal of the present invention is to provide a method for reducing the resistance between the Indium Tin Oxide (ITO) layer and P-type GaN contact layer. With carrier penetration in the digital transparent layer, the resistance between the ITO layer and the P-type contact layer become an ohmic contact, thus the resistance is reduced.

The third goal of the present invention is to provide a material, in which carrier penetration can take place.

The present invention employs a material of indium tin oxide, which has a superior photo-penetrability, to replace the Ni/Au in forming the transparent conductive layer 7. However, because it is not an ohmic contact between the ITO material and the P-type GaN material, it is necessary to add another layer of digital transparent layer 10, as shown in FIG. 4. The effect of the carrier penetration will make the two said material become an ohmic contact, so that the resistance is reduced.

According to the aforementioned goals, the present invention provides a structure and a manufacturing method for fabricating GaN LEDs with a digital transparent layer. First, a substrate is provided, and a GaN semiconductor stack is formed on top of the said substrate. The said GaN semiconductor stack includes, from the bottom up, an N-type GaN contact layer, a light-emitting stack layer and a P-type GaN contact layer. Then, a digital transparent layer is formed on top of the said P-type contact layer. A dry etching is performed to etch through the digital transparent layer, the P-type contact layer, the light-emitting stack layer, and finally reach and stop at the N-type contact layer to form an N-metal forming area. Then, a first ohmic contact electrode is formed on the P-type contact layer for P-type ohmic contact, and a second ohmic contact electrode is formed on N-metal forming area for N-type ohmic contact. Finally, a bump pad is formed on the said first ohmic contact electrode and the said second ohmic contact electrode, respectively.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows a structure of a conventional GaN light emitting diode.

FIGS. 2A-D show the method for manufacturing the GaN LEDs according to the structure in FIG. 1.

FIG. 3 shows the structure of the present invention.

FIG. 4 shows a cross section diagram of the digital transparent layer.

FIGS. 5A-D show the method for manufacturing the GaN LEDs according to the structure in FIG. 4.

FIG. 6 shows the relationship between wavelength (in nm) and the thickness of the Ni/Au layer and the indium tin oxide layer.

FIG. 7 shows the characteristic relationship between the current and the voltage for the conventional GaN LEDs, and the present invention.

FIG. 8 shows the characteristic relationship between the illumination and the current for the conventional GaN LEDs, and the present invention.

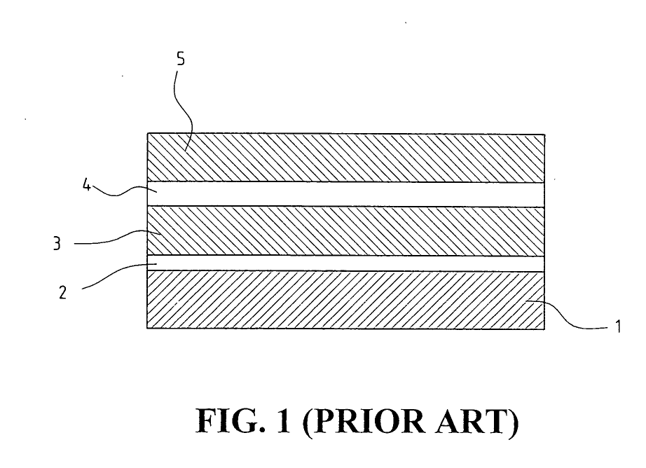

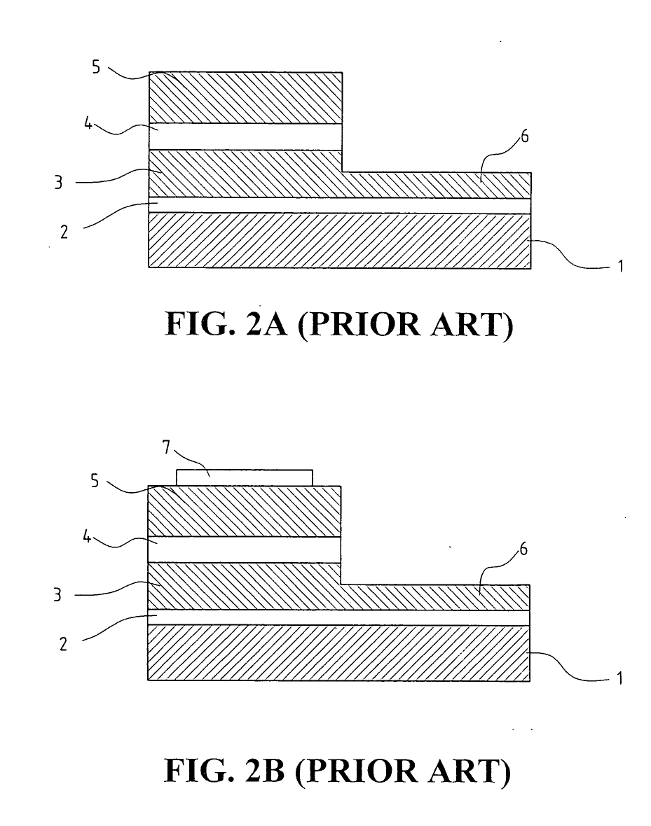

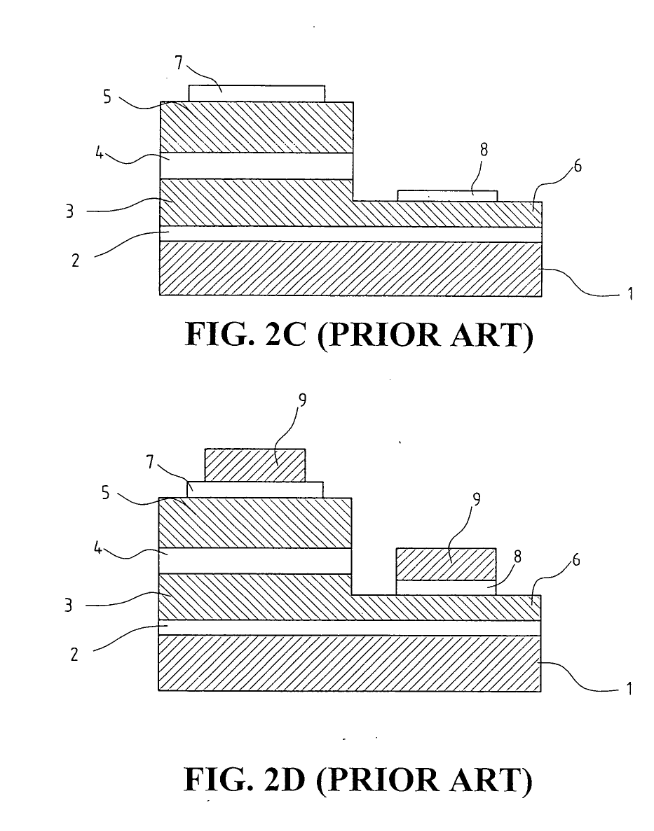

### DETAILED DESCRIPTION OF THE INVENTION

The preferred embodiment of the present invention is described as below. However, some parts of the figures are not drawn in accordance with the physical proportion due to the illustrative purpose. The emphasis on some parts or components is to provide a more clear description of the invention to those who are skilled in this field.

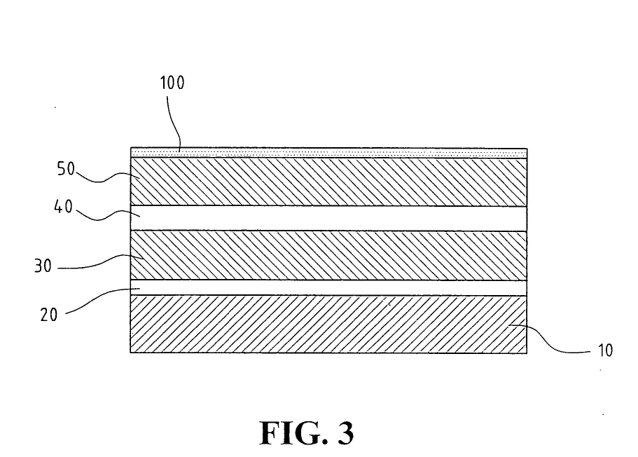

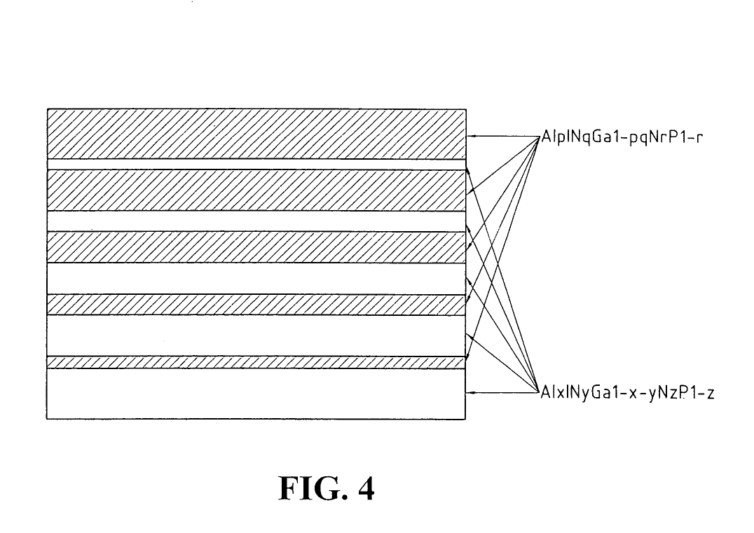

As shown in FIG. 3, a substrate 10 is provided. A buffer layer 20 is formed on the said substrate 10 by using metal organic chemical vapor deposition (MOCVD), molecular beam epitaxy, vapor phase epitaxy (VPE), or liquid phase epitaxy (LPE). The present invention preferred the MOCVD method. By using the same method, an N-type GaN layer 30 is formed on top of the buffer layer 20, a light-emitting stack layer 40 is formed on top of the N-type GaN layer 30, a P-type GaN layer 50 is formed on top of the light-emitting stack layer 40, and finally, a digital transparent layer 100 is formed on top of the P-type GaN layer 50. The cross section of the digital transparent layer 100 is shown in FIG. 4. As seen in FIG. 4, the digital transparent layer 100 is stacked by layers made of two types of material. The thickness of the layers in the stack made of one type of material increases from 10 Å to 90 Å, denoted as Al(x)In(y)Ga(1−x−y)N(z)P(1−z), and the other decreases from 90 Å to 10 Å, denoted as Al(p)In(q)Ga(1−p−q)N(r)P(1−r), where the values of x, y, z, p, q, r, are all between 0 and 1.

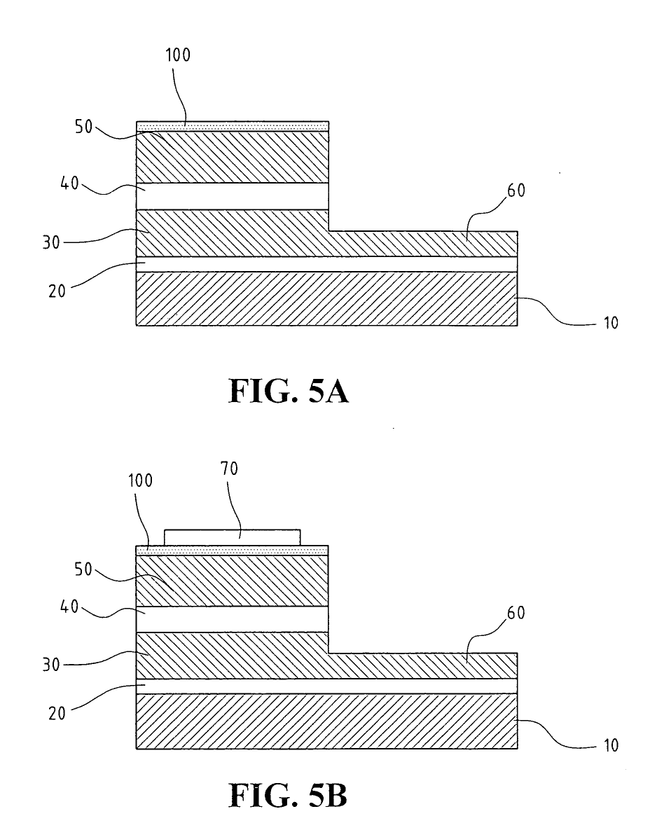

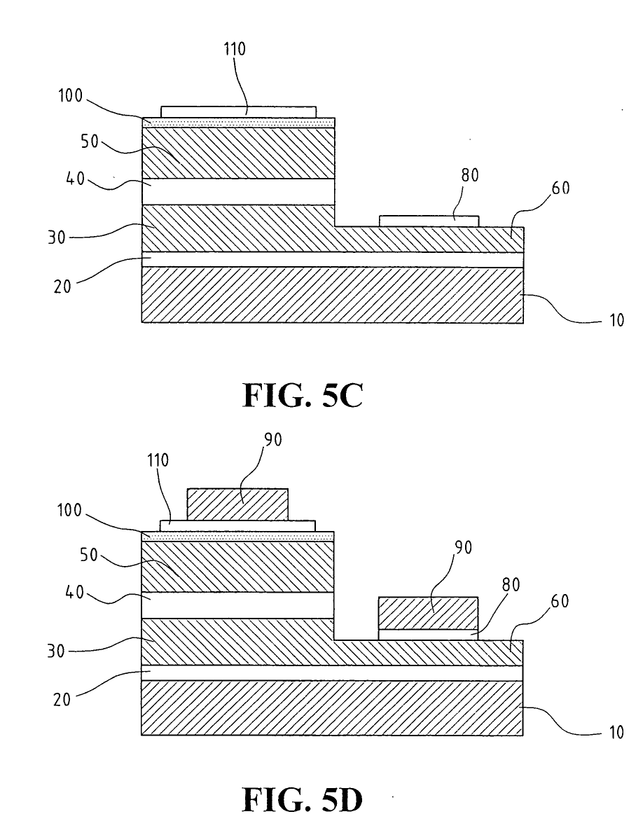

The next step is to use a dry etching method to etch downward through the digital transparent layer 100, P-type GaN layer 50, light emitting stack layer 40, and finally reach and stop at the N-type layer 30. The etching will form an N-metal forming area of about 10000 Å. The preferred dry etching method used in the present invention is the inductively coupled plasma-reactive ion etching (ICP-RIE), as shown in FIG. 5A.

The next step is to use electronic gun vapor-phase steam electroplate technique, or other similar techniques, such as heat-resist vapor-phase steam electroplate, or splash vapor-phase steam electroplate technique to form an ITO layer 110 on top of the P-type GaN layer 50. The ITO layer 110, which is transparent and can be used as a P-type ohmic contact, serves as a first ohmic contact electrode. The preferred method used in the present invention is the splash vapor-phase steam electroplate technique, and the preferred thickness of the ITO layer 110 is 1000 Å to 4000 Å, although it could range from 100 Å to 20000 Å, as shown in FIG. 5B.

The next step is to form, by using the aforementioned techniques, an N-metal 80, used is used as an N-type ohmic contact, on top of the N-metal forming area 60. The N-type omhic contact is used as a second ohmic contact electrode. The preferred technique used in the present invention is the electronic gun vapor-phase steam electroplate technique. The material used for N-metal 80 is Ti/Al of size about 150 Å/1500 Å, or other materials, such as Ti/Al/Ti/Au (150 Å/1500 Å/2000 Å/1000 Å), or Ti/Al/Ni/Au (150 Å/1500 Å/2000 Å/1000 Å), as shown in FIG. 5C.

Finally, a bump pad 90 of diameter about 100 um each is formed on the ITO layer 110 and N-metal 80, respectively. The preferred technique used in the present invention is electronic gun vapor-phase steam electroplate technique. The bump pad 90 is made of Ti/Au (150 Å/20000 Å), or other materials, such as, Ti/Al/Ti/Au (150 Å/1500 Å/2000 Å/10000 Å), or Ti/Al/Pt/Au (150 Å/1500 Å/2000 Å/10000 Å), as shown in FIG. 5D. Hence, a GaN LED is manufactured in accordance with the methods described in the present invention.

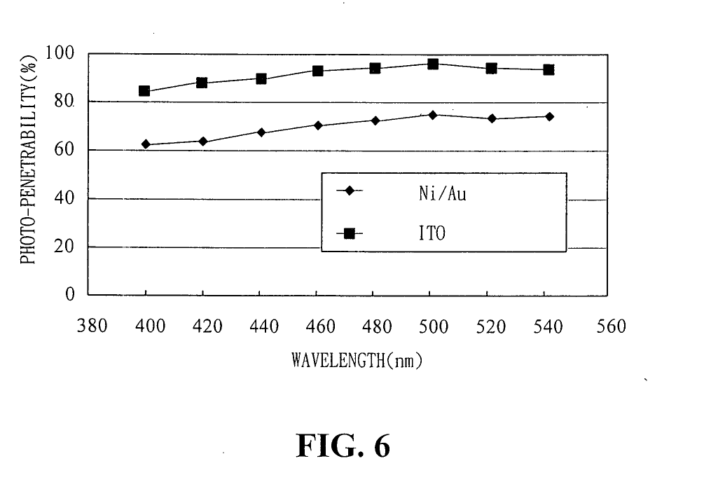

FIG. 6 shows the relationship between wavelength (in nm) and the thickness of the Ni/Au layer and the indium tin oxide layer. As seen in the figure, photo-penetrability for the Ni/Au layer is 73% when the wavelength is 500 nm, while the value for ITO layer is 93% when the wavelength is 500 nm. Obviously, the photo-penetrability of the ITO layer is much better than that of the Ni/Au layer.

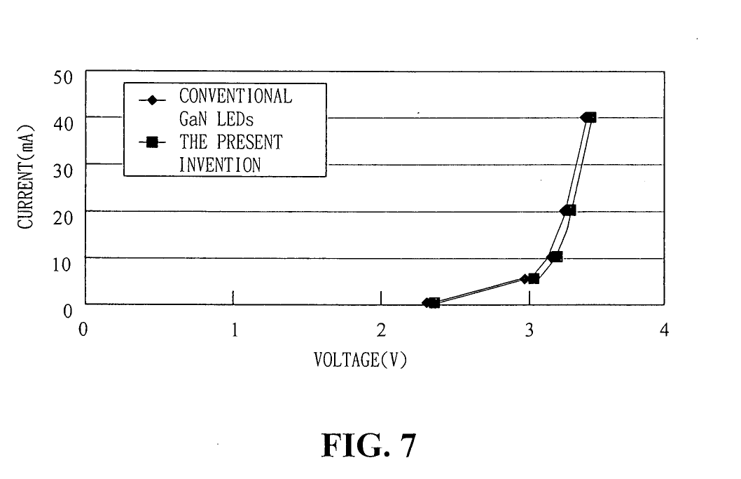

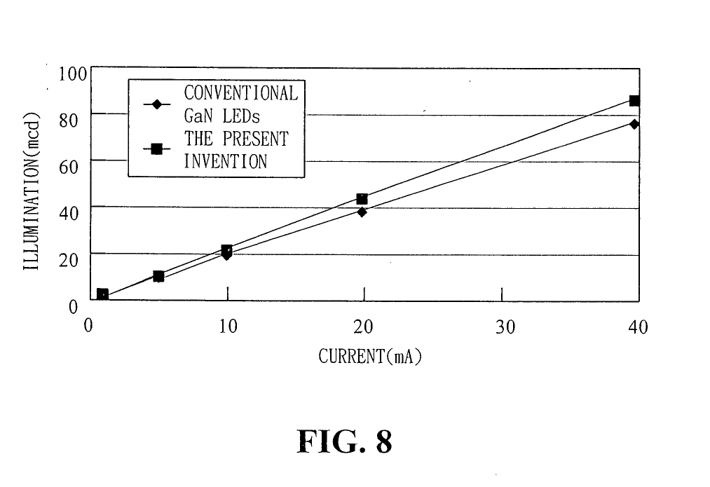

FIG. 7 shows the characteristic relationship between the current and the voltage for the conventional GaN LEDs, and the present invention. FIG. 8 shows the characteristic relationship between the illumination and the current for the conventional GaN LEDs, and the present invention. As sseen from the figure, although the electrical characteristics are quite similar in both diodes structure, the illumination of the diodes manufactured as the present invention increases about 20%. It proves that the present invention is a progress over the prior arts.

While we have shown and described the embodiment in accordance with the present invention, it should be clear to those skilled in the art that further embodiments may be made without departing from the scope of the present invention.

1. A method for manufacturing GaN light emitting diodes, comprising the steps of:
providing a substrate;
forming a GaN semiconductor stack layer on said substrate, wherein said GaN semiconductor stack layer includes, from bottom up, an N-type GaN contact layer, a light emitting stack layer and a P-type contact layer;
forming a digital transparent layer on said p-type GaN contact layer;
using dry etching technique to etch downward through said digital transparent layer, said P-type GaN contact layer, said light emitting layer, said N-type GaN contact layer, and forming an N-metal forming area within said N-type GaN contact layer;
forming a first ohmic contact electrode on said P-type contact layer to serve as P-type ohmic contact;
forming a second ohmic contact electrode on said N-metal forming area to serve as N-type ohmic contact; and
forming bump pads on said first ohmic contact electrode and said second ohmic contact electrode respectively.

2. The method for manufacturing GaN light emitting diodes as claimed in claim 1, wherein said digital transparent layer is formed by using one of the following methods: metal organic chemical vapor deposition (MOCVD), molecular beam epitaxy, vapor phase epitaxy (VPE), or liquid phase epitaxy (LPE).

3. The method for manufacturing GaN light emitting diodes as claimed in claim 1, wherein said digital transparent layer is made of a material having photo-penetrability higher than 80% for wavelength ranging between 380 nm and 560 nm, and carrier penetration capable of taking place within said material.

4. The method for manufacturing GaN light emitting diodes as claimed in claim 1, wherein said digital transparent layer is made of Al(x)In(y)Ga(1−x−y)N(z)P(1−z) having thickness increasing from 10 Å to 90 Å, or Al(p)In(q)Ga(1−p−q)N(r)P(1−r) having thickness decreasing from 90 Å to 10 Å, wherein the values of x, y, z, p, q, r, are between 0 and 1.

5. The method for manufacturing GaN light emitting diodes as claimed in claim 1, wherein said dry etching technique is inductively coupled plasma-reactive ion etching (ICP-RIE).

6. The method for manufacturing GaN light emitting diodes as claimed in claim 5, wherein said inductively coupled plasma-reactive ion etching technique forms an N-metal forming area of about 10000 Å.

7. The method for manufacturing GaN light emitting diodes as claimed in claim 1, wherein said first ohmic contact electrode is made of indium tin oxide.

8. The method for manufacturing GaN light emitting diodes as claimed in claim 1, wherein said first ohmic contact layer is formed by using splash vapor-phase steam electroplate technique.

9. The method for manufacturing GaN light emitting diodes as claimed in claim 1, wherein the thickness of said first ohmic contact ranges from 100 Å to 20000 Å.

10. The method for manufacturing GaN light emitting diodes as claimed in claim 1, wherein the thickness of said first ohmic contact ranges from 1000 Å to 4000 Å.

11. The method for manufacturing GaN light emitting diodes as claimed in claim 1, wherein said second ohmic contact electrode is made of Ti/Al, Ti/Al/Ti/Au, or Ti/Al/Ni/Au.

12. The method for manufacturing GaN light emitting diodes as claimed in claim 11, wherein the thickness of said second ohmic contact electrode is 150 Å/1500 Å for Ti/Al, 150 Å/1500 Å/2000 Å/1000 Å for Ti/Al/Ti/Au, or 150 Å/1500 Å/2000 Å/1000 Å for Ti/Al/Ni/Au.

13. The method for manufacturing GaN light emitting diodes as claimed in claim 1, wherein said GaN stack layer comprises a buffer layer being placed between said substrate and said N-type contact layer.

14. The method for manufacturing GaN light emitting diodes as claimed in claim 1, wherein said bump pad is made of Ti/Au, Ti/Al/Ti/Au, or Ti/Al/Pt/Au.

15. The method for manufacturing GaN light emitting diodes as claimed in claim 14, wherein the thickness of said bump pad is 150 Å/20000 Å for Ti/Au, 150 Å/1500 Å/2000 Å/10000 Å for Ti/Al/Ti/Au, or 150 Å/1500 Å/2000 Å/10000 Å for Ti/Al/Pt/Au.

16. The method for manufacturing GaN light emitting diodes as claimed in claim 1, wherein said digital transparent layer has conductivity which is either P-type, N-type or I-type.
